(19) United States
(12) Patent Application Publication
(10) Pub. No.: US 2021/0408068 A1
(43) Pub. Date: Dec. 30, 2021

(54) ARRAY SUBSTRATE, METHOD OF MANUFACTURING SAME, AND DISPLAY DEVICE

(71) Applicant: WUHAN CHINA STAR OPTOELECTRONICS TECHNOLOGY CO., LTD., Wuhan, Hubei (CN)

(72) Inventors: Juncheng XIAO, Wuhan, Hubei (CN); Yong XU, Wuhan, Hubei (CN); Fei AI, Wuhan, Hubei (CN); Guoheng YIN, Wuhan, Hubei (CN)

(73) Assignee: WUHAN CHINA STAR OPTOELECTRONICS TECHNOLOGY CO., LTD., Wuhan, Hubei (CN)

(21) Appl. No.: 16/757,130

(22) PCT Filed: Nov. 14, 2019
(86) PCT No.: PCT/CN2019/118432

§ 371 Date: Apr. 17, 2020

(30) Foreign Application Priority Data
Sep. 25, 2019 (CN) 201910912144.7

(51) Int. Cl. H01L 27/12

(52) U.S. Cl. CPC H01L 27/1222; H01L 27/127

(57) ABSTRACT

An array substrate, a method of manufacturing the same, and a display device are provided. The array substrate includes a first active layer and a second active layer. A material of the first active layer comprises low temperature poly-silicon. A material of the second active layer comprises an oxide semiconductor. The first active layer and the second active layer are disposed at different layers and horizontally staggered.

### FIELD

The present disclosure relates to display technologies, and more particularly, to an array substrate, a method of manufacturing the same, and a display device.

### BACKGROUND

Liquid crystal displays (LCDs) have many advantages such as thin body, power saving, no radiation, etc., has been widely used in consumer electronics, such as: mobile phone, LCD TV, personal digital assistant (PDA), digital camera, laptop computer or computer screen, etc., and dominates a field of display device. In recent years, LCD devices have exhibited development trends of high resolution, narrow bezels, and low power consumption. In order to find a more energy-efficient way in limited space and battery capacity, low temperature poly-oxide (LTPO) display technologies are developed. This technology usually uses low temperature poly-silicon (LTPS) thin film transistors in the gate driver on array (GOA) area, and uses indium gallium zinc oxide (IGZO) thin film transistors in the active area (AA). Among them, LTPS technology has high mobility, small size, and fast charging, which can effectively reduce a frame size, while IGZO technology has small dark current and can be driven at low frequencies, thereby achieving narrow bezels and low power consumption functions.

However, LTPS-TFT and IGZO-TFT have many design and process incompatibility issues. For example, the hydrogen fluoride solution in the LTPS process will etch IGZO. The dielectric layer in the LTPS-TFT contains a large amount of residual hydrogen atoms which will destroy IGZO electrical properties, film thickness requirements of LTPS-TFT and IGZO-TFT common film layers are not consistent and deep and shallow hole etching issue. Therefore, there is a need to solve the above issues.

### SUMMARY

In view of the above, the present disclosure provides an array substrate, a method of manufacturing the same, and a display device to solve issues of incompatibility of layer design between the LTPS-TFT and the oxide TFT, that result in electrical properties destroying of oxide TFT, and to solve issues of inconsistency of film thickness requirements of common film layers and deep and shallow hole etching.

In order to achieve above-mentioned object of the present disclosure, one embodiment of the disclosure provides an array substrate including a first active layer and a second active layer. A material of the first active layer includes low temperature poly-silicon. A material of the second active layer includes an oxide semiconductor. The first active layer and the second active layer are disposed at different layers and horizontally staggered.

In one embodiment of the disclosure, the array substrate further includes a first insulating layer, a first gate layer, a dielectric layer, a first source/drain layer, and a second insulating layer. The first insulating layer is disposed on the first active layer. The first gate layer is disposed on the first insulating layer. A part of the first gate layer corresponds to the first active layer. The dielectric layer is disposed on the first insulating layer and the first gate layer. The first source/drain layer is disposed on the dielectric layer and connected opposite ends of the first active layer passing through the dielectric layer and the first insulating layer. The second insulating layer is disposed on the dielectric layer and the first source/drain layer. The second active layer is disposed on a surface of the second insulating layer opposite to another surface of the second insulating layer facing the dielectric layer.

In one embodiment of the disclosure, the array substrate further includes a second gate layer, an etching stop layer, a second source/drain layer, and a planarization layer. The second gate layer is disposed at a same layer with the first source/drain layer, and disposed corresponding to the second active layer. The second gate layer is connected to another part of the first gate layer. The etching stop layer is disposed on the second active layer and the second insulating layer. The second source/drain layer is disposed on the etching stop layer and connected to opposite ends of the second active layer passing through the etching stop layer. An end of part of the second source/drain layer is connected to the second active layer, and another end of part of the second source/drain layer is connected to the first source/drain layer. The planarization layer is disposed on the second source/drain layer and the etching stop layer.

In one embodiment of the disclosure, the array substrate further includes a touch tracing layer, a common electrode layer, a passivation layer, and a pixel electrode layer. The touch tracing layer is disposed between the etching stop layer and the planarization layer and disposed at a same layer with the second source/drain layer. The common electrode layer is disposed on the planarization layer and connected to the touch tracing layer passing through the planarization layer. The passivation layer is disposed on a surface of the common electrode layer opposite to another surface of the common electrode layer facing the planarization layer. The pixel electrode layer is disposed on the common electrode layer and connected to the second source/drain layer passing through the passivation layer and the common electrode layer.

In one embodiment of the disclosure, the array substrate further includes a substrate layer. The substrate layer is disposed on a surface of the first active layer opposite to another surface of the first active layer facing the second active layer.

Furthermore, another embodiment of the disclosure provides a method of manufacturing an array substrate, including steps of:

providing a substrate layer; providing a first active layer on the substrate layer; and providing a second active layer. The first active layer and the second active layer are disposed at different layers and horizontally staggered;

A material of the first active layer includes low temperature poly-silicon, and a material of the second active layer includes an oxide semiconductor.

In one embodiment of the disclosure, the method of manufacturing the array substrate further includes steps between the step of providing the first active layer and the step of providing the second active layer. The steps include:

providing a first insulating layer on the first active layer and the substrate; providing a first gate layer on the first insulating layer; providing a dielectric layer on the first gate layer and the first insulating layer; providing a first source/drain layer and a second gate layer on the dielectric layer; and providing a second insulating layer on the first source/drain layer, the second gate layer, and the dielectric layer.

In one embodiment of the disclosure, the method of manufacturing the array substrate further includes steps of:

providing an etching stop layer on the second active layer and the second insulating layer; providing a second source/drain layer and a touch tracing layer on the etching stop layer; and providing a planarization layer on the second source/drain layer, the touch tracing layer, and the etching stop layer.

In one embodiment of the disclosure, the method of manufacturing the array substrate further include steps of:

providing a common electrode layer on the planarization layer; providing a passivation layer on the common electrode layer; and providing a pixel electrode layer on the passivation layer.

Furthermore, another embodiment of the disclosure provides a display device including the array substrate above mentioned.

In comparison with prior art, the array substrate and the display device of the disclosure provides the first active layer and the second active layer disposed at different layers and horizontally staggered to prevent from etching on the second active layer by hydrogen fluoride solution in the preparing process and prevent from destroying electrical properties of the second active layer by hydrogen atoms or other etching mediums. Meanwhile, the disclosure provides the etching stop layer to reduce a passivation layer in prior art to simplify structure of the array substrate and to reduce cost.

The method of manufacturing the array substrate of the disclosure provides the first active layer and the second active layer in the array substrate disposed at different layers and horizontally staggered to prevent from etching on the second active layer by hydrogen fluoride solution in the preparing process of the first active layer and prevent from destroying properties of the second active layer by residual hydrogen atoms or other etching mediums in the dielectric layer and the first active layer. Meanwhile, the disclosure provides the etching stop technologies to prevent from destroying on the second active layer when etching the second source/drain layer.

### BRIEF DESCRIPTION OF DRAWINGS

FIG. 1 is a schematic view of layers of an array substrate according to an embodiment of the present disclosure.

FIG. 2 is a schematic flowchart of a preparing method according to an embodiment of the present disclosure.

FIG. 3 is a schematic view of layers after step S5 according to an embodiment of the present disclosure.

FIG. 4 is a schematic view of layers after step S9 according to an embodiment of the present disclosure.

FIG. 5 is a schematic view of layers after step S11 according to an embodiment of the present disclosure.

Reference numbers of the present disclosure are as follows:

1000: display device, 100: array substrate, 1: substrate layer, 1A: base layer, 1B: buffer layer, 2: first active layer, 3: first insulating layer, 4: first gate layer, 5: dielectric layer, 6: first source/drain layer, 7: second insulating layer, 8: second gate layer, 9: second active layer, 10: etching stop layer, 11:second source/drain layer, 12: touch tracing layer, 13: planarization layer, 14: common electrode layer, 15: passivation layer, 16: pixel electrode layer, 17: deep hole, 18: shallow hole, 19: through hole.

### DETAILED DESCRIPTION

The following description of the embodiments is provided by reference to the drawings and illustrates the specific embodiments of the present disclosure. Directional terms mentioned in the present disclosure, such as “up,” “down,” “top,” “bottom,” “forward,” “backward,” “left,” “right,” “inside,” “outside,” “side,” “peripheral,” “central,” “horizontal,” “peripheral,” “vertical,” “longitudinal,” “axial,” “radial,” “uppermost” or “lowermost,” etc., are merely indicated the direction of the drawings. Therefore, the directional terms are used for illustrating and understanding of the application rather than limiting thereof

One embodiment of the disclosure provides a display device 1000. The display device 1000 includes an array substrate 100. The display device can be any product or parts including display function such as LCD, mobile phone, tablet, laptop computer, digital camera, or GPS, etc.

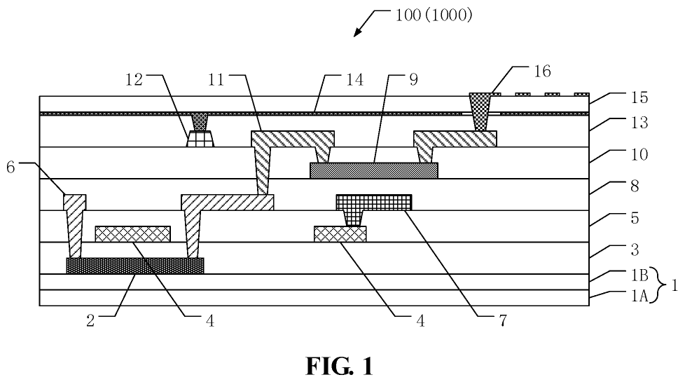

Referring to FIG. 1, one embodiment of the disclosure provides an array substrate 100 including two kinds of thin film transistors. One of the thin film transistors includes a first active layer 2 and another thin film transistor includes a second active layer 9. The first active layer 2 and the second active layer 9 are disposed at different layers and horizontally staggered in the array substrate 100. A material of the first active layer 2 includes low temperature poly-silicon. A material of the second active layer 9 includes an oxide semiconductor. The oxide semiconductor may be indium gallium zinc oxide, indium gallium oxide, gallium zinc oxide, indium zinc oxide, indium tin zinc oxide, indium tin oxide, indium zinc oxide, zinc tin oxide, Metal oxide materials such as indium aluminum zinc oxide.

The array substrate 100 includes a substrate layer 1. The substrate layer 1 includes a buffer layer 1B and a base layer 1A. The buffer layer 1B and the base layer 1A are stacked. The base layer 1A is an insulating substrate. A material thereof includes an insulating material such as glass or quartz. The base layer 1A is configured to protect a whole structure of the array substrate 100. The buffer layer 1B is disposed on the base layer 1A. The first active layer 2 is disposed on a surface of the buffer layer 1B opposite to another surface of the buffer layer 1B facing the base layer 1A. The buffer layer 1B is configured to protect a structure between every element of the array substrate 100 to reduce damage came from moving or vibrating.

In one embodiment of the disclosure, the array substrate further includes a first insulating layer 3, a first gate layer 4, a dielectric layer 5, a first source/drain layer 6, and a second insulating layer 7 disposed on the first active layer 2.

The first insulating layer 3 covers a surface of the first active layer 2 and the buffer layer 1B away from the base layer 1A. The first insulating layer 3 is configured to protect the first active layer 2 and insulate the first active layer 2 from the first gate layer 4. The first gate layer 4 is disposed on a surface of the first insulating layer 3 away from the first active layer 2. A part of the first gate layer 4 corresponds to the first active layer 2. Another part of the first gate layer 4 is disposed near the second active layer 9. The dielectric layer 5 covers a surface of the first insulating layer 3 and the first gate layer 4 away from the first active layer 2 to insulate and protect the first gate layer 4. The first source/drain layer 6 is disposed on a surface of the dielectric layer 5 away from the first gate layer 4 and connected opposite ends of the first active layer 2 passing through the dielectric layer 5 and the first insulating layer 3. The second insulating layer 7 covers a surface of the dielectric layer 5 and the first source/drain layer 6 away from the first gate layer 4 to insulate and protect the first source/drain layer 6.

The second active layer 9 is disposed on a surface of the second insulating layer 7 opposite to another surface of the second insulating layer 7 facing the first source/drain layer 6. In one embodiment of the disclosure, the array substrate further includes an etching stop layer 10, a second source/drain layer 11, and a planarization layer 13 disposed on the second active layer 9.

The etching stop layer 10 is disposed on a surface of the second active layer 9 and the second insulating layer 7 away from the first source/drain layer 6. The etching stop layer 10 is configured to insulate and protect the second active layer 9 from damaging when preparing the second source/drain layer 11, and to prevent an electrical property of the second active layer 9 from damaging caused by impurities in the planarization layer 13. Meanwhile, it can omit a layer of passivation layer on the second source/drain layer 11 to simplify a structure of the array substrate 100. The second source/drain layer 11 is disposed on a surface of the etching stop layer 10 away from the second active layer 9 and connected to opposite ends of the second active layer 9 passing through the etching stop layer 10. An end of part of the second source/drain layer 11 near the first source/drain layer 6 is connected to the first source/drain layer 6 passing through the etching stop layer 10 and the second insulating layer 7. The planarization layer 13 is disposed on a surface of the second source/drain layer 11 and the etching stop layer 10 away from the second active layer 9 to flat a surface of the array substrate 100.

In one embodiment of the disclosure, the array substrate further includes a touch tracing layer 12 between the etching stop layer 10 and the planarization layer 13. The touch tracing layer 12 is disposed at a same layer with the second source/drain layer 11 as metal traces of a touch panel to provide electrical current or voltage for the touch panel.

In one embodiment of the disclosure, the array substrate further includes a common electrode layer 14, a passivation layer 15, and a pixel electrode layer 16 disposed on the planarization layer 13. The common electrode layer 14 is disposed on the planarization layer 13 away from the second source/drain layer 11 and connected to the touch tracing layer 12 passing through the planarization layer 13. The passivation layer 15 is disposed on a surface of the common electrode layer 14 to passivate, insulate, and protect the common electrode layer 14. The pixel electrode layer 16 is disposed on a surface of the passivation layer 15 away from the common electrode layer 14 and connected to the second source/drain layer 11 passing through the passivation layer 15 and the common electrode layer 14. The common electrode layer 14 does not contact the pixel electrode layer 16 where the pixel electrode layer 16 penetrating the common electrode layer 14. The common electrode layer is insulating from the pixel electrode layer 16. The common electrode layer 14 and the pixel electrode layer 16 form a storage capacity to store and charge for other elements of the array substrate 100.

A material of the buffer layer 1B, the first insulating layer 3, the dielectric layer 5, the second insulating layer 7, the etching stop layer 10, the flat layer 13, and the passivation layer 15 include one or more of inorganic materials such as silicon oxide and silicon nitride. The first gate layer 4, the first source/drain layer 6, the second gate layer 8, the second source/drain layer 11, the touch tracing layer 12, the common electrode layer 14, and the pixel electrode layer 16 may be made of a metal or alloy includes copper, titanium, molybdenum, aluminum, or the like, which has excellent conductivity.

The array substrate 100 and the display device 1000 including the array substrate 100 of the disclosure provides the first active layer 2 and the second active layer 9 disposed at different layers and horizontally staggered to prevent from etching on the second active layer 9 by hydrogen fluoride solution in the preparing process and prevent from destroying electrical properties of the second active layer 9 by hydrogen atoms or other etching mediums. Meanwhile, the disclosure provides the etching stop layer 10 to reduce a passivation layer in prior art to simplify structure of the array substrate 100 and to reduce cost.

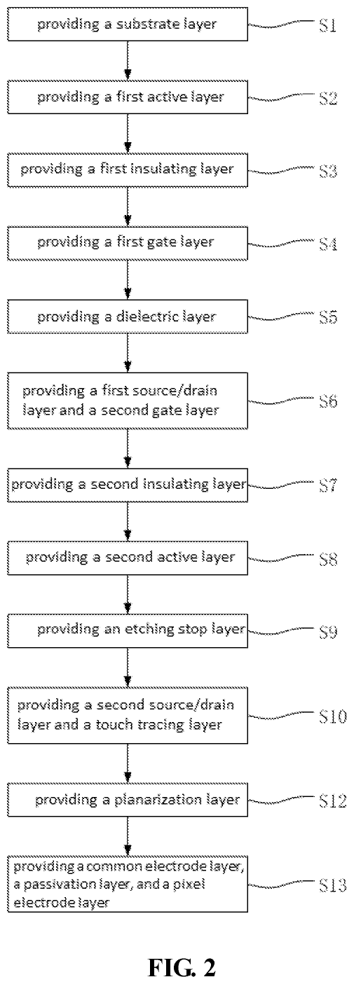

As shown in FIG. 2, furthermore, another embodiment of the disclosure provides a method of manufacturing the array substrate 100, including steps of:

Step S1: providing a substrate layer 1. The substrate layer 1 includes a base layer 1A and a buffer layer 1B. The base layer 1A is an insulating substrate such as a glass substrate or a quartz substrate. The buffer layer 1B is deposited on a surface of the base layer 1A by a deposition method.

Step S2: providing a first active layer 2. Deposit a layer of amorphous silicon on the buffer layer 1B of the substrate layer 1. Transfer the amorphous silicon to a low temperature poly-silicon to form the first active layer 2 by annealing and ion doping.

Step S3: providing a first insulating layer 3. Deposit inorganic material such as silicon oxide or silicon nitride on a surface of the first active layer 2 and the buffer layer 1B away from the base layer 1A to form a first insulating layer 3.

Step S4: providing a first gate layer 4. Deposit a layer of metal or alloy on the first insulating layer 3 away from the first active layer 2 and etch pattern to form a first gate layer 4.

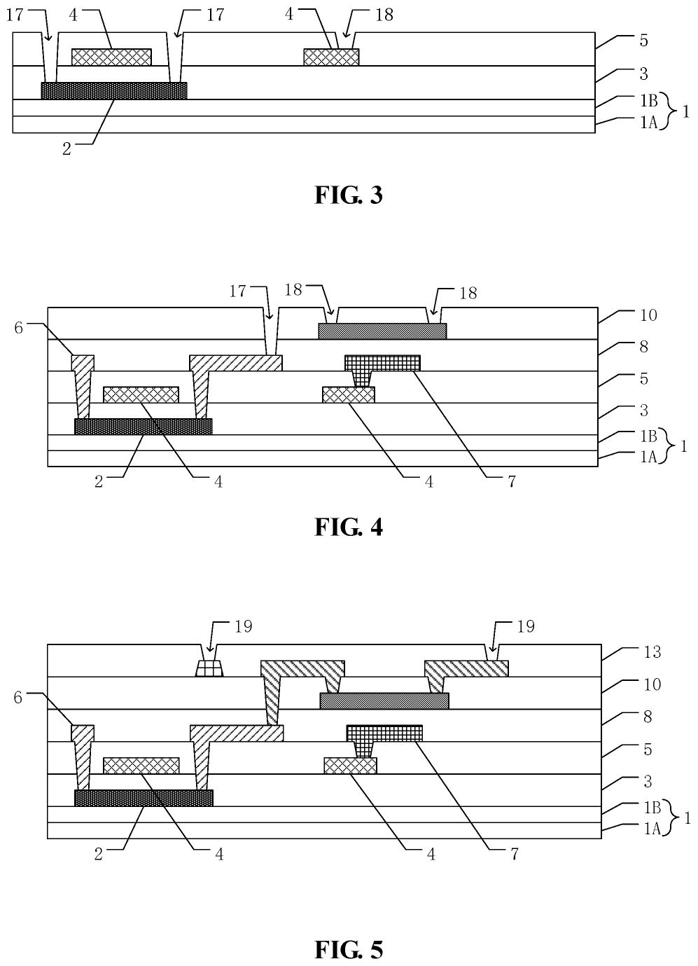

Step S5: providing a dielectric layer 5. Deposit a dielectric layer 5 on a surface of the first gate layer 4 and the first insulating layer 3 away from the first active layer 2. Etch the insulating layer 5 to form a deep hole 17 and a shallow hole 18. As shown in FIG. 3, the deep hole 17 corresponds to two opposite ends of the first active layer 2 and penetrates the dielectric layer 5 and the first insulating layer 3 to a surface of the first active layer 2. The shallow hole 18 corresponds to a side of the first gate layer 4 near the second active layer 9 and penetrates the dielectric layer 5 to a surface of the first gate layer 4. Remove oxide on the first active layer 2 by hydrofluoric solution

Step S6: providing a first source/drain layer 6 and a second gate layer 8. Deposit a layer of metal or alloy on a surface of the dielectric layer 5 away from the first gate layer 4. Fill the metal or the alloy in the deep hole 17 and the shallow hole 18 in the dielectric layer 5. Pattern the deposited metal or the alloy on the dielectric layer 5 to from the first source/drain layer 6 and the second gate layer 8. The first source/drain layer 6 connects with the two opposite ends of the first active layer 2 through the deep hole 17. The second gate layer 8 connects with the first gate layer 4 through the shallow hole 18.

Step S7: providing a second insulating layer 7. Deposit an inorganic material such as silicon oxide or silicon nitride on the first source/drain layer 6 and the second gate layer 8 to from the second insulating layer 7.

Step S8: providing a second active layer 9. Deposit a layer of metal oxide material such as indium gallium zinc oxide, indium gallium oxide, gallium zinc oxide, indium zinc oxide, indium tin zinc oxide, indium tin oxide, indium zinc oxide, zinc tin oxide, indium aluminum zinc oxide on a surface of the second insulating layer 7 away from the first source/drain layer 6 and pattern the metal oxide material to form the second active layer 9 corresponding to the second gate layer 8.

Step S9: providing an etching stop layer 10. Deposit a layer of silicon oxide on a surface of the second active layer 9 and the second insulating layer 7 away from the first source/drain layer 6 to form the etching stop layer 10. Provide the deep hole 17 and the shallow hole 18 on the etching stop layer 10 by etching. As shown in FIG. 4, the deep hole 17 corresponds to the first source/drain layer 6 and penetrates the etching stop layer 10 and the second insulating layer to a surface of the first source/drain layer 6. The shallow hole 18 corresponds to two opposite ends of the second active layer 9 and penetrates the etching stop layer 10 to a surface of the second active layer 9.

Step S10: providing a second source/drain layer 11 and a touch tracing layer 12. Deposit a layer of metal or alloy on the etching stop layer 10 away from the second active layer 9, fill the metal or alloy material in the deep hole 17 and shallow hole 18 in the etching stop layer 10, and pattern the deposited metal or alloy on the etching stop layer 10 by etching to form the second source/drain layer 11 and the touch tracing layer 12. The second source/drain layer 11 connects with two opposite ends of the second active layer 9 through the shallow hole 18. An end of the second source/drain layer 11 near the first source/drain layer 6 connects with the first source/drain layer 6 through the deep hole 17.

Step S11: providing a planarization layer 13. Deposit a layer of silicon oxide or silicon nitride on the second source/drain layer 11 and the touch tracing layer 12 to form the planarization layer 13. Provide a through hole 19 on the planarization layer 13 by etch stopper layer (ESL) technology. As shown in FIG. 5, the through hole 19 passes through the planarization layer 13 and corresponds to the touch tracing layer 12 and the second source/drain layer 11.

Step S12: providing a common electrode layer 14, a passivation layer 15, and a pixel electrode layer 16. Deposit metal or alloy on the planarization layer 13 to from the common electrode layer 14. The common electrode layer 14 is filled in the through hole 19 corresponding to the touch tracing layer 12 to connect with the touch tracing layer 12. Deposit silicon oxide on the common electrode layer 14 and pattern by etching to form the passivation layer 15. Deposit metal or alloy on the passivation layer 15 to form the pixel electrode layer 16. The pixel electrode layer 16 connects with the second source/drain layer 11 through the passivation layer 15, the common electrode layer 14, and the through hole 19 in the planarization layer 13 corresponding to the second source/drain layer 11.

The method of manufacturing the array substrate 100 of the disclosure prevents from etching on the second active layer 9 by hydrogen fluoride solution and prevent from destroying properties of the second active layer 9 by hydrogen atoms or other etching mediums and the first active layer. Meanwhile, the disclosure provides the etching stop technologies to prevent from destroying on the second active layer 9 when etching the second source/drain layer 11.

The present disclosure has been described by the above embodiments, but the embodiments are merely examples for implementing the present disclosure. It must be noted that the embodiments do not limit the scope of the invention. In contrast, modifications and equivalent arrangements are intended to be included within the scope of the invention.

What is claimed is:

1. An array substrate, comprising a first active layer and a second active layer, wherein a material of the first active layer comprises low temperature poly-silicon, a material of the second active layer comprises an oxide semiconductor, and the first active layer and the second active layer are disposed at different layers and horizontally staggered.

2. The array substrate according to claim 1, further comprising:
a first insulating layer disposed on the first active layer;
a first gate layer disposed on the first insulating layer, wherein a part of the first gate layer corresponds to the first active layer;
a dielectric layer disposed on the first insulating layer and the first gate layer;
a first source/drain layer disposed on the dielectric layer and connected opposite ends of the first active layer passing through the dielectric layer and the first insulating layer; and
a second insulating layer disposed on the dielectric layer and the first source/drain layer, wherein the second active layer is disposed on a surface of the second insulating layer opposite to another surface of the second insulating layer facing the dielectric layer.

3. The array substrate according to claim 2, further comprising:
a second gate layer disposed at a same layer with the first source/drain layer, and disposed corresponding to the second active layer, wherein the second gate layer is connected to another part of the first gate layer;
an etching stop layer disposed on the second active layer and the second insulating layer;
a second source/drain layer disposed on the etching stop layer and connected to opposite ends of the second active layer passing through the etching stop layer, wherein an end of part of the second source/drain layer is connected to the second active layer, and another end of part of the second source/drain layer is connected to the first source/drain layer; and
a planarization layer disposed on the second source/drain layer and the etching stop layer.

4. The array substrate according to claim 2, further comprising:
a touch tracing layer disposed between the etching stop layer and the planarization layer and disposed at a same layer with the second source/drain layer;
a common electrode layer disposed on the planarization layer and connected to the touch tracing layer passing through the planarization layer;
a passivation layer disposed on a surface of the common electrode layer opposite to another surface of the common electrode layer facing the planarization layer; and
a pixel electrode layer disposed on the common electrode layer and connected to the second source/drain layer passing through the passivation layer and the common electrode layer.

5. The array substrate according to claim 1, further comprising:
a substrate layer disposed on a surface of the first active layer opposite to another surface of the first active layer facing the second active layer.

6. A method of manufacturing an array substrate, comprising steps of:
providing a substrate layer;
providing a first active layer on the substrate layer; and
providing a second active layer, wherein the first active layer and the second active layer are disposed at different layers and horizontally staggered;
wherein a material of the first active layer comprises low temperature poly-silicon, a material of the second active layer comprises an oxide semiconductor.

7. The method of manufacturing the array substrate according to claim 6, further comprising steps between the step of providing the first active layer and the step of providing the second active layer, wherein the steps comprises:
providing a first insulating layer on the first active layer and the substrate
providing a first gate layer on the first insulating layer;
providing a dielectric layer on the first gate layer and the first insulating layer;
providing a first source/drain layer and a second gate layer on the dielectric layer; and
providing a second insulating layer on the first source/drain layer, the second gate layer, and the dielectric layer.

8. The method of manufacturing the array substrate according to claim 7, further comprising steps of:
providing an etching stop layer on the second active layer and the second insulating layer;
providing a second source/drain layer and a touch tracing layer on the etching stop layer; and
providing a planarization layer on the second source/drain layer, the touch tracing layer, and the etching stop layer.

9. The method of manufacturing the array substrate according to claim 8, further comprising steps of:
providing a common electrode layer on the planarization layer;
providing a passivation layer on the common electrode layer; and
providing a pixel electrode layer on the passivation layer.

10. A display device, comprising the array substrate according to claim 1.
